(19) United States
(12) Patent Application Publication
(10) Pub. No.: US 2026/0239618 A1
(43) Pub. Date: Aug. 13, 2026

(54) SEMICONDUCTOR DEVICE

(71) Applicant: Kioxia Corporation, Tokyo (JP)

(72) Inventor: Tadashi IGUCHI, Yokkaichi Mie (JP)

(73) Assignee: Kioxia Corporation, Tokyo (JP)

(21) Appl. No.: 19/321,852

(22) Filed: Sep. 8, 2025

(30) Foreign Application Priority Data
Feb. 13, 2025 (JP) 2025-021392

(51) Int. Cl. H10B 43/27; H10B 43/10

(52) U.S. Cl. CPC H10B 43/27; H10B 43/10

(57) ABSTRACT

A semiconductor device according to an embodiment includes a source, an insulator, a first conductive layer in contact with the insulator in a first region, a second conductive layer disposed between the source and the first conductive layer, the second conductive layer being in contact with the insulator in a second region having a lower height than a height of the first region, a first insulating layer disposed between the first conductive layer and the second conductive layer, the first insulating layer being in contact with the insulator in a third region that connects the first region and the second region in a first direction, and a first columnar conductor part disposed at a boundary between the first region and the third region, the first columnar conductor part extending in a second direction perpendicular to the first direction, the first columnar conductor part being connected to the first conductive layer.

### CROSS-REFERENCE TO RELATED APPLICATION(S)

This application is based upon and claims the benefit of priority from the prior Japanese Patent Application No. 2025-021392, filed on Feb. 13, 2025, the entire contents of which are incorporated herein by reference.

### FIELD

An embodiment of the present disclosure relates to a semiconductor device.

### BACKGROUND

Semiconductor packaging using a NAND flash memory as a semiconductor device is known. In order to increase the capacity of such a NAND flash memory, a three-dimensional NAND flash memory with a configuration in which many memory cells are laminated has been put into practical use. In such a laminated three-dimensional NAND flash memory, it is an object to improve the operation rate and reliability.

### BRIEF DESCRIPTION OF THE DRAWINGS

FIG. 1 is a top view showing an overall configuration of a semiconductor device according to an embodiment.

FIG. 2 is a perspective view showing a configuration of a semiconductor device near a contact region HUR according to the present embodiment.

FIG. 3 is a perspective view showing a configuration of a memory cell region MCR and a contact region HUR of a semiconductor device according to an embodiment.

FIG. 4 is a top view showing a configuration of a contact region HUR of a semiconductor device according to an embodiment.

FIG. 5 is a cross-sectional view showing a configuration of a contact plug of a semiconductor device according to an embodiment.

FIG. 6 is a cross-sectional view showing a configuration of a contact plug of a semiconductor device according to an embodiment.

FIG. 7 is a cross-sectional view showing a method for manufacturing a semiconductor device according to an embodiment.

FIG. 8 is a cross-sectional view showing a method for manufacturing a semiconductor device according to an embodiment.

FIG. 9 is a cross-sectional view showing a method for manufacturing a semiconductor device according to an embodiment.

FIG. 10 is a cross-sectional view showing a method for manufacturing a semiconductor device according to an embodiment.

FIG. 11 is a cross-sectional view showing a method for manufacturing a semiconductor device according to an embodiment.

FIG. 12 is a cross-sectional view showing a method for manufacturing a semiconductor device according to an embodiment.

FIG. 13 is a cross-sectional view showing a configuration of a contact plug of a se miconductor device according to an embodiment.

FIG. 14 is a cross-sectional view showing a method for manufacturing a semiconductor device according to an embodiment.

FIG. 15 is a cross-sectional view showing a method for manufacturing a semiconductor device according to an embodiment.

FIG. 16 is a cross-sectional view showing a method for manufacturing a semiconductor device according to an embodiment.

FIG. 17 is a cross-sectional view showing a method for manufacturing a semiconductor device according to an embodiment.

### DETAILED DESCRIPTION

Hereinafter, a semiconductor device according to an embodiment of the present disclosure will be described in detail with reference to the drawings. In the following description, elements having substantially the same functions and configurations are denoted by the same reference signs or the same reference signs with additional letters, and will be described redundantly only when necessary. Each of the embodiments described below exemplifies an apparatus and a method for embodying a technical idea of the present embodiment. Various modifications may be made to the embodiments without departing from the spirit of the disclosure. These embodiments and modifications thereof are included in the scope of the disclosure described in the claims and equivalents thereof.

In the drawings, the widths, thicknesses, shapes, and the like of the respective portions may be schematically represented in comparison with the actual embodiments for clarity of explanation, but the drawings are merely examples, and do not limit the interpretation of the present disclosure. In the present specification and the drawings, elements having the same functions as those described with respect to the above-described drawings are denoted by the same reference signs, and redundant descriptions thereof may be omitted.

In the present specification, the expressions “α includes A, B, or C” and the like does not exclude the case where α includes a plurality of combinations of A to C unless otherwise specified. Furthermore, these expressions do not exclude the case where α includes other elements.

The following embodiments can be combined with each other as long as there is no technical contradiction.

In each embodiment of the present disclosure, a direction from a source toward a memory cell is referred to as above. Conversely, a direction from the memory cell to the source is referred to as below. As described above, for convenience of explanation, the term “above” or “below” is used to describe the configuration, but for example, the source and the memory cell may be disposed so that the vertical relationship is opposite to that shown in the figure. Further, in the following explanation, for example, the expression “a memory cell on a source” merely describes the vertical relationship between the source and the memory cell as described above, and another member may be disposed between the source and the memory cell.

A semiconductor device according to an embodiment includes a source, an insulator disposed above the source, a first conductive layer in contact with the insulator in a first region, a second conductive layer disposed between the source and the first conductive layer, the second conductive layer being in contact with the insulator in a second region having a lower height from the source than a height from the source of the first region, a first insulating layer disposed between the first conductive layer and the second conductive layer, the first insulating layer being in contact with the insulator in a third region that connects the first region and the second region in a first direction, and a first columnar conductor part disposed at a boundary between the first region and the third region, the first columnar conductor part extending in a second direction perpendicular to the first direction, the first columnar conductor part being connected to the first conductive layer.

### First Embodiment

### Overall Configuration of Semiconductor Device

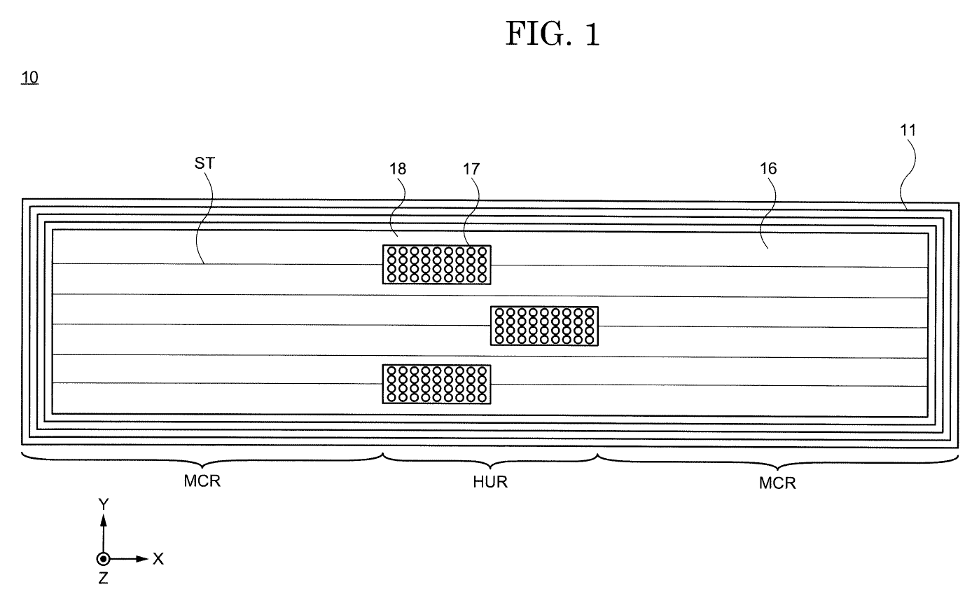

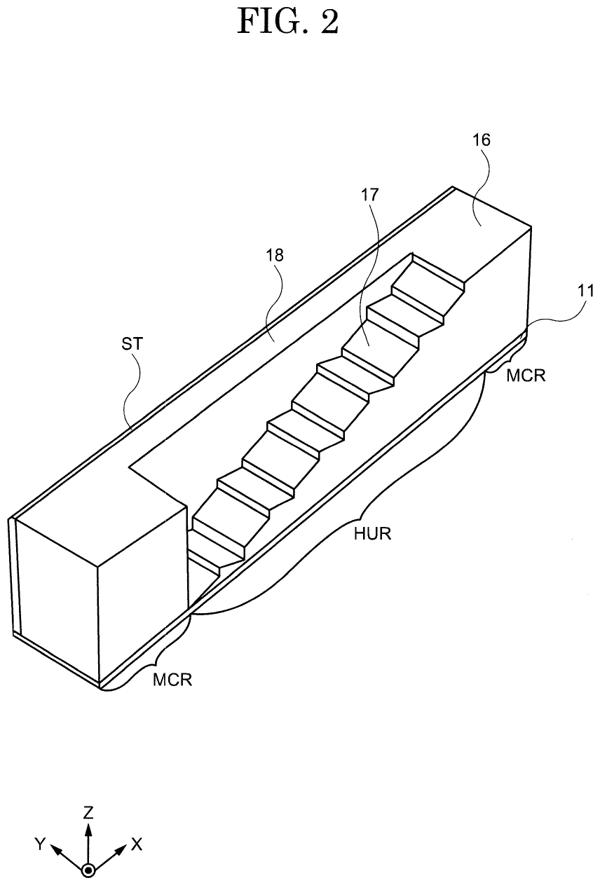

An overall configuration of the semiconductor device according to the present embodiment will be described with reference to FIG. 1 and FIG. 2. FIG. 1 is a top view showing an overall configuration of a semiconductor device 10 according to the present embodiment. FIG. 2 is a perspective view showing a configuration near a contact region HUR of a certain block BLK according to the present embodiment. In FIG. 1 and FIG. 2, two directions parallel to the main surface of a source 11 and orthogonal to each other are referred to as a direction X and a direction Y, and a plane parallel to the main surface of the source 11 is referred to as a XY plane. A direction orthogonal to both the direction X and the direction Y is referred to as a direction Z (laminated direction).

For example, the semiconductor device 10 is a NAND flash memory device. The semiconductor device 10 includes a source 11. Two memory cell regions MCR and the contact region HUR are defined on the source 11. A memory cell array 16, including a plurality of memory cells laminated three-dimensionally, is formed in the memory cell region MCR. Specifically, a source-side select gate transistor, a plurality of (e.g., 64) memory cell transistors, and a drain-side select gate transistor are connected in series in a direction (direction Z) perpendicular to the main surface (XY plane) of the source 11 to form a memory string. In addition, a dummy cell transistor may be included at both ends of the plurality of memory cell transistors connected in series or at a portion between the plurality of memory cell transistors. The memory cell array 16 includes a laminated body in which a plurality of conductive layers serving as a source-side select gate line, a word line, and a drain-side select gate line connected to the respective transistors is laminated via an insulating layer. The plurality of conductive layers of the memory cell array 16 extends in the contact region HUR to form the laminated wiring structure 17 and a bridge part 18.

The contact region HUR is provided between the two memory cell regions MCR. The contact region HUR is disposed substantially in the center of the semiconductor device 10 in the direction X (extending direction of a slit ST). The memory cell array 16 spaced apart in the direction X is electrically connected to the laminated wiring structure 17 in the contact region HUR by the bridge part 18 adjacent in the direction Y. The bridge part 18 includes the laminated body in which the plurality of conductive layers corresponding to the wiring drawn from the source-side select gate line, the word line, and the drain-side select gate line connected to the respective transistors of the memory cell array 16 are laminated via the insulating layer, respectively. The bridge part 18 extends in the direction X (extending direction of the slit ST), and electrically connects the memory cell array 16 spaced apart in the direction X to each of the plurality of conductive layers.

The slit ST is formed in the semiconductor device 10. the slit ST extends in the laminated direction (direction Z) of the memory cell array 16, passes through the memory cell array 16, and reaches the source 11. The slit ST extends in the direction X and separates the memory cell array 16 into a plurality of blocks BLK in the direction Y. An insulating layer is formed in the slit ST.

### Configuration of Memory Cell Region MCR and Contact Region HUR

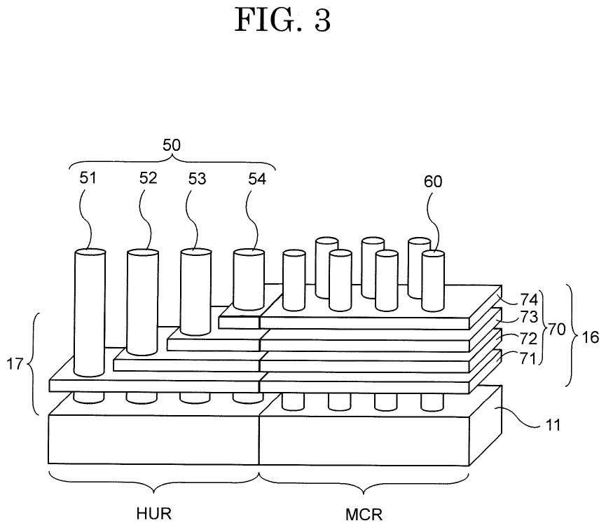

FIG. 3 is a perspective view showing a configuration of the memory cell region MCR and the contact region HUR of the semiconductor device according to the present embodiment. In order to prevent the illustration from becoming complicated, the conductive member is shown, and the insulating member is omitted. In FIG. 3, a part where the member is not shown is insulated by using an insulating material such as silicon dioxide.

In the memory cell region MCR, the memory cell array 16 is formed on the source 11. Fo example, a semiconductor substrate using silicon single crystal, a semiconductor layer using polysilicon, or a conductive layer using tungsten is used as the source 11. The memory cell array 16 has a conductive layer 71, a conductive layer 72, a conductive layer 73, and a conductive layer 74 (when there is no need to distinguish between the conductive layers 71 to 74, they are collectively referred to as a conductive layer 70) extending substantially parallel to the surface of the source 11. The memory cell array 16 has a laminated body in which a plurality of conductive layers 70 is laminated via the insulating layer, respectively. In this case, for example, the material of the conductive layer 70 may be tungsten or molybdenum. For example, the material of the insulating layer may be oxygen-containing silicon using a silicon dioxide film (SiO₂), such as TEOS (Tetra Ethyl Ortho Silicate). Although only four layers of the conductive layer 70 are shown in the figure, many layers are laminated, such as 33 layers and 65 layers. These conductive layers 70 correspond to the source-side select gate line, the word line, or the drain-side select gate line connected to the transistor.

In the memory cell region MCR, a memory pillar 60 penetrating the plurality of conductive layers 70 and the plurality of insulating layers is formed. The memory pillar 60 has a cylindrical shape, and a block insulating film including a silicon dioxide film, a charge storage film including a silicon nitride film, a tunnel insulating film including a silicon dioxide film, a semiconductor channel including an amorphous or polycrystalline silicon film, and a silicon dioxide film are laminated from the outer peripheral side toward the center. A portion of the charge storage film positioned between the conductive layers 71, 72, 73, and 74 corresponding to the select gate line or word line and the semiconductor channel functions as a part of a non-volatile memory cell that traps a carrier.

The upper end of the semiconductor channel of the memory pillar 60 is connected to a bit BL (not shown). A plurality of memory pillars 60 selected one by one from each block BLK separated in the direction Y by the slit ST is connected to a common bit line BL extending in the direction Y.

In the contact region HUR, a laminated wiring structure 17 is formed on the source 11. Also in the contact region HUR, a plurality of insulating layers and a plurality of conductive layers 70 extending from the memory cell region MCR are formed. The laminated wiring structure 17 has the conductive layer 71, the conductive layer 72, the conductive layer 73, and the conductive layer 74 extending substantially parallel to the surface of the source 11. The laminated wiring structure 17 has a laminated body in which the plurality of conductive layers 70 is laminated via the insulating layer. Although only four layers of the conductive layer are shown in the figure, as described above, many layers are laminated, such as 33 layers and 65 layers. Further, in the contact region HUR, the plurality of conductive layers 70 correspond to the wiring drawn from the source-side select gate line, the word line, or the drain-side select gate line.

In the contact region HUR, the conductive layers 71, 72, 73, and 74 corresponding to the wiring drawn from the select gate line or the word line are formed in a stepped structure in the direction X so as to expose a part of the lower layer conductive layer.

A contact plug 50 penetrating the plurality of conductive layers 70 and the plurality of insulating layers is formed in the contact region HUR. The contact plug 50 has a substantially cylindrical shape, and details thereof will be described later. For example, the material of the contact plug 50 may be tungsten.

The conductive layers 71, 72, 73, and 74 are connected to corresponding contact plugs 51, 52, 53, and 54 (when there is no need to distinguish between the contact plugs 51 to 54, they are collectively referred to as the contact plug 50) in a step region exposed in the stepped structure. In this case, the conductive layer 71 is connected to the contact plug 51, the conductive layer 72 is connected to the contact plug 52, the conductive layer 73 is connected to the contact plug 53, and the conductive layer 74 is connected to the contact plug 54. Although only four contact plugs 50 are shown in the figure, for example, the same number of contact plugs as the plurality of conductive layers are disposed. Each contact plug 50 is insulated from the lower layer conductive layer 70 other than the conductive layer 70 to which it is connected via an insulating layer (not shown). Each contact plug 50 is drawn onto the laminated wiring structure 17 via a contact hole penetrating an insulator (not shown).

### Configuration of Laminated Wiring Structure and Contact Plug

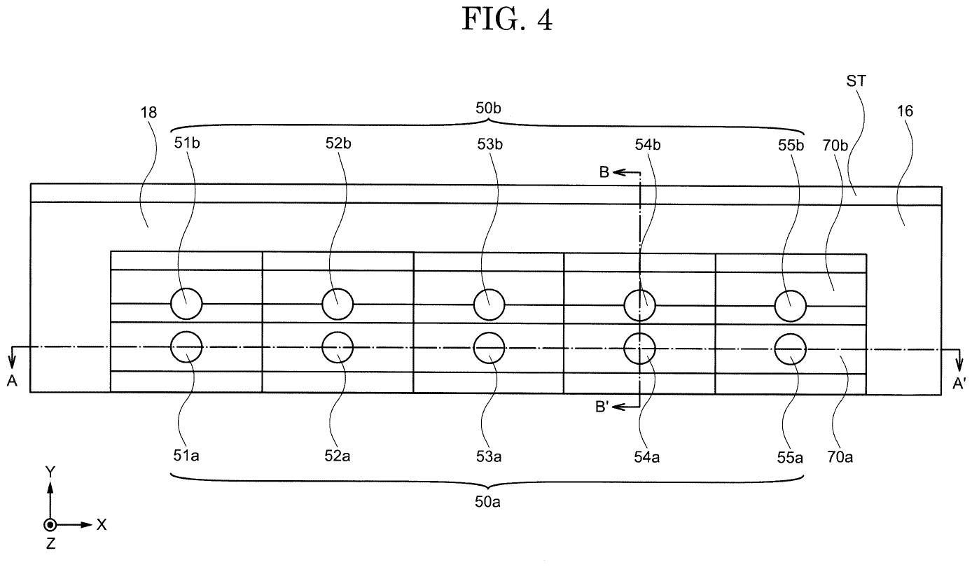

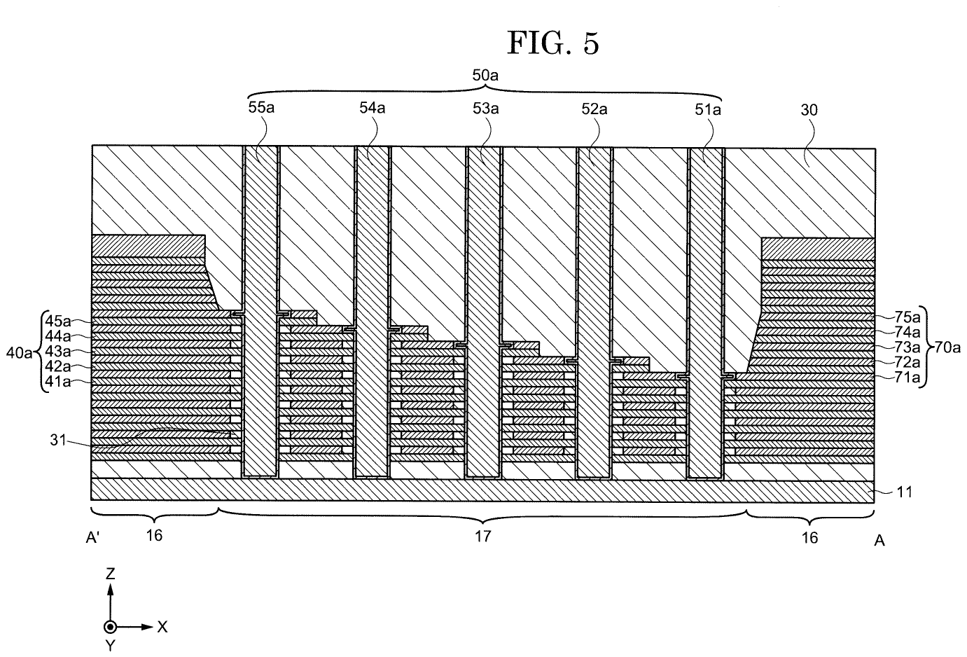

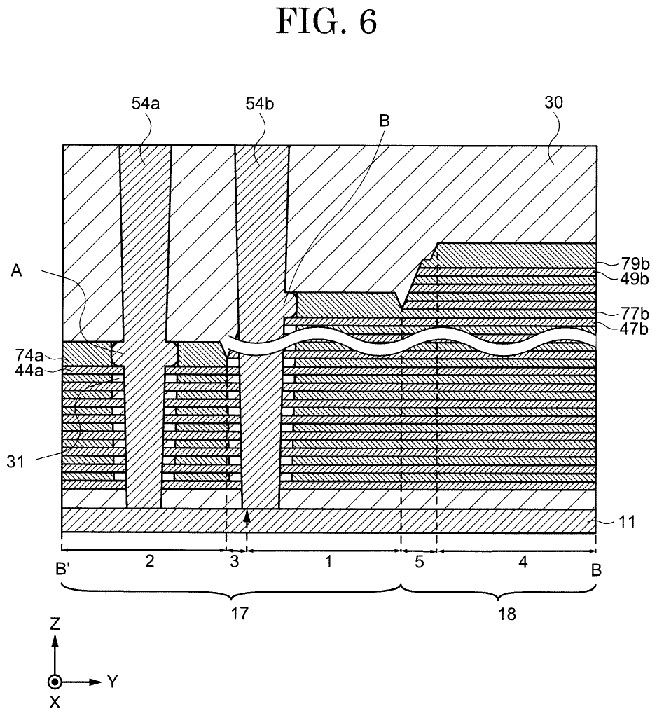

A configuration of the laminated wiring structure and the contact plug according to the present embodiment will be described with reference to FIG. 4 to FIG. 6. FIG. 4 is a top view showing an outline of the contact region HUR of a certain block BLK according to the present embodiment. FIG. 5 and FIG. 6 are cross-sectional views showing a configuration of the contact plug of the semiconductor device according to the present embodiment. FIG. 5 is a cross-sectional view of the contact region HUR shown in FIG. 4 cut along a line A-A′, and FIG. 6 is a cross-sectional view of the contact region HUR shown in FIG. 4 cut along a line B-B′.

As shown in FIG. 4, the laminated wiring structure 17 for connecting the contact plug 50 to each of the plurality of conductive layers 70 is provided in the contact region HUR. In the laminated wiring structure 17, a plurality of contact plugs 50 is disposed in a square grid along the direction X and the direction Y. In the laminated wiring structure 17, the plurality of conductive layers 70 is formed in a stepped structure so as to be exposed from the conductive layer 70 in the upper stage (opposite to the source 11). In addition, an insulator 30 is disposed on the laminated wiring structure 17 (opening region). However, for convenience of explanation, this is omitted in FIG. 4.

The plurality of contact plugs 50 includes a plurality of contact plugs 51a, 52a, 53a, 54a, and 55a aligned in the direction X (in this case, when there is no need to distinguish between the contact plugs 51a to 55a, they are collectively referred to as a contact plug 50a) and a plurality of contact plugs 51b, 52b, 53b, 54b, and 55b (in this case, when there is no need to distinguish between the contact plugs 51b to 55b, they are collectively referred to as a contact plug 50b). A plurality of contact plugs 50a is disposed in the direction Y opposite to the bridge part 18 and is connected to a plurality of conductive layers 70a. A plurality of contact plugs 50b is disposed between the bridge part 18 and the contact plug 50a in the direction Y and is connected to a plurality of conductive layers 70b (in this case, when there is no need to distinguish between the conductive layer 70a and a conductive layer 70b, they are collectively referred to as the conductive layer 70).

As shown in FIG. 5, the contact plugs 50a adjacent to each other in the direction X a disposed for each conductive layer 70a. in this case, a conductive layer 71a disposed on an insulating layer 41a is connected to the contact plug 51a, a conductive layer 72a disposed on an insulating layer 42a is connected to the contact plug 52a, a conductive layer 73a disposed on an insulating layer 43a is connected to the contact plug 53a, a conductive layer 74a disposed on an insulating layer 44a is connected to the contact plug 54a, and a conductive layer 75a disposed on an insulating layer 45a is connected to the contact plug 55a (when there is no need to distinguish between the insulating layers 41a to 45a, they are collectively referred to as an insulating layer 40a, and when there is no need to distinguish between the conductive layers 71a to 75a , they are collectively referred to as the conductive layer 70a).

As shown in FIG. 6, the contact plug 50b adjacent to the contact plug 50a in the direction Y is disposed for each of the plurality of conductive layers 70b. In FIG. 6, although an example in which the contact plug 54b adjacent to the contact plug 54a in the direction Y is connected to a conductive layer 77b on the plurality of layers is shown, the present disclosure is not limited to this. The plurality of contact plugs 50b may be disposed between the bridge part 18 and the contact plug 50a in the direction Y. In this case, the conductive layer 77b disposed on an insulating layer 47b is connected to the contact plug 54b.

As shown in FIG. 6, the laminated wiring structure 17 includes a first region 1, a second region 2, and a third region 3 in the direction Y. The bridge part 18 includes a fourth region 4 and a fifth region 5 in the direction Y. The first region 1 and the second region 2 and the fourth region 4 are step regions of a stepped structure, and the conductive layer 70 corresponding to the upper surface of the laminated body is exposed and substantially parallel to the source 11. The conductive layer 70 exposed on the upper surface of the laminated body is in contact with the insulator 30. The height of the first region 1 from the source 11 is lower than that of the fourth region 4, and the height of the second region 2 from the source 11 is lower than that of the first region 1. For example, the conductive layer 77b is exposed in the first region 1, the conductive layer 74a below the conductive layer 77b (the source 11 side) is exposed in the second region 2, and a conductive layer 79b above the conductive layer 77b (opposite side from the source 11) is exposed in the fourth region 4. The step in the step region of the stepped structure is not particularly limited (when there is no need to distinguish between the conductive layers 77b to 79b, they are collectively referred to as the conductive layer 70b).

The third region 3 and the fifth region 5 are tapered regions connecting the step region of the stepped structure in the direction Y, and an insulating layer 40 (when there is no need to distinguish between the insulating layers 44a . . . 47b . . . 49b, they are collectively referred to as the insulating layer 40). The third region 3 connects the first region 1 and the second region 2, and the fifth region 5 connects the first region 1 and the fourth region 4. For example, the insulating layer 47b below the conductive layer 77b (the source 11 side) is exposed in the third region 3, and the insulating layer 49b below the conductive layer 79b (the source 11 side) is exposed in the fifth region 5 (when there is no need to distinguish between the insulating layers 47b . . . 49b, they are collectively referred to as an insulating layer 40b).

Thicknesses of the conductive layer 77b exposed in the first region 1, the conductive layer 74a exposed in the second region 2, and the conductive layer 79b exposed in the fourth region 4 in the direction Z (laminated direction) are thicker than the lower layer conductive layer 70. In addition, the thickness of the conductive layer 77b exposed in the first region 1 is larger than the thickness of the conductive layer 77b in the fourth region 4, and the thickness of the conductive layer 74a exposed in the second region 2 is larger than the thickness of the conductive layer 74a in the first region 1. The insulator 30 embedding the stepped structure is disposed on the laminated body of the insulating layer 40 and the conductive layer 70.

The contact plug 50a and the contact plug 50b (when there is no need to distinguish between the contact plug 50a and the contact plug 50b, they are collectively referred to as the contact plug 50) extend in the laminated direction (direction Z) of the laminated body, pass through the insulator 30 and the laminated body of the insulating layer 40 and the conductive layer 70, and reach the source 11. The contact plug 50a is disposed in the second region 2. The contact plug 50b is disposed in the first region 1 and the third region 3. The width of the second region 2 in the direction Y is substantially the same as the sum of the width of the first region 1 in the direction Y and the width of the third region 3 in the direction Y. Therefore, the contact plug 50b is disposed at the boundary (dotted arrow) between the first region 1 and the third region 3.

The contact plug 50a has a widening portion A protruding in the connecting direction wit the conductive layer 70a. For example, the contact plug 54a has a disk-shaped widening portion A having a diameter (width in the direction XY) larger than that of a portion facing the insulating layer 44a under one layer at a portion facing the conductive layer 74a in the step region of the stepped structure. The widening portion A of the contact plug 54a is connected to the conductive layer 74a in the second region 2 in the direction XY.

The contact plug 50b has a widening portion B protruding in the connecting direction wi the conductive layer 70b. For example, the contact plug 54b has a fan-shaped widening portion B having a diameter (width in the direction Y) larger than that of a portion facing the insulating layer 47b under one layer at a portion facing the conductive layer 77b in the step region of the stepped structure. The widening portion B of the contact plug 54b is connected to the conductive layer 77b in the first region 1 in the direction Y.

An insulating film 31 is disposed between the contact plug 50 and the lower layer conductive layer 70 other than the conductive layer 70 connected via the widening portion A or the widening portion B. The contact plug 50 and the lower layer conductive layer 70, other than the conductive layer 70 connected via the widening portion A or the widening portion B, can be insulated by the insulating film 31 being disposed.

As described above, in the laminated wiring structure according to the present embodiment, even if the contact plug 54b is disposed in the tapered region of the stepped structure, the insulating film 31 is disposed between the conductive layer 70b below the conductive layer 77b and the side surface of the contact plug 54b, and the contact plug 54b and the conductive layer 77b can be securely connected, so that the semiconductor device 10 with improved reliability can be provided.

The width in the direction Y of the second region 2 in which the contact plug 54a is formed can be designed to be substantially the same as the sum of the width in the direction Y of the first region 1 in which the contact plug 54b is formed and the width in the direction Y of the third region 3, and the width in the direction Y of the laminated wiring structure 17 can be reduced. Therefore, the width in the direction Y of the bridge part 18 can be increased and an increase in resistance of the bridge part 18 can be suppressed, so that a semiconductor device in which the operation rate (read and program operation rate) is improved can be provided.

### Method for Manufacturing Laminated Wiring Structure

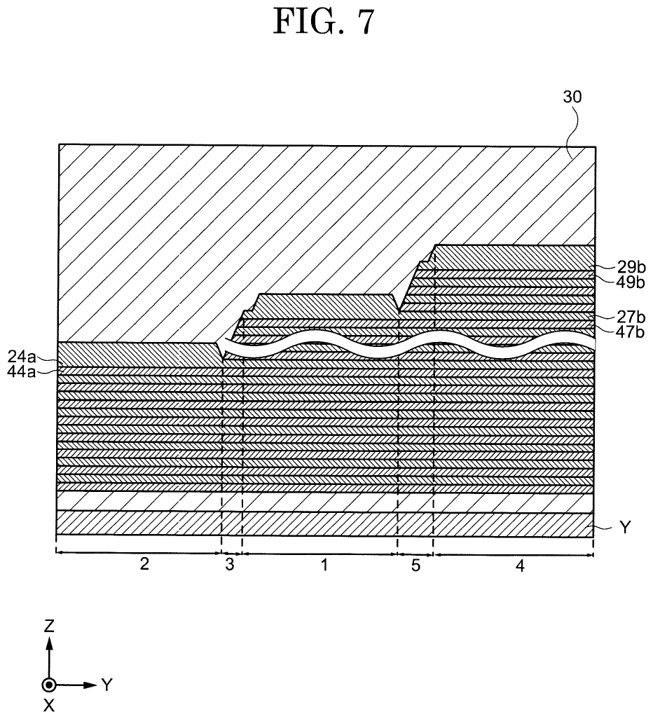

A method for manufacturing the laminated wiring structure 17 according to the present embodiment will be described with reference to FIG. 7 to FIG. 12.

First, the insulating layer 40 and a sacrificial layer 20 (when there is no need to distinguish between sacrificial layers 24a . . . 27b . . . 29b, they are collectively referred to as the sacrificial layer 20) are alternately deposited on a semiconductor substrate Y one by one to form a laminated body. For example, the insulating layer 40 and the sacrificial layers 20 are deposited using a CVD apparatus. The alternately laminated insulating layer 40 and the sacrificial layer 20 are formed so as to be in contact with each other. The insulating layer 40 and the sacrificial layer 20 are periodically laminated in a direction perpendicular to the main surface of the semiconductor substrate Y. In the present embodiment, the material of the insulating layer 40 may be a silicon dioxide film (SiO₂). The material of the sacrificial layer 20 may be a silicon nitride film (SiN). However, the material of the sacrificial layer 20 is not limited to this, and may be, for example, silicon or a metal such as tungsten.

As shown in FIG. 7, the laminated body of the insulating layer 40 and the sacrificial layer 20 is formed in a stepped structure so as to expose the lower layer sacrificial layer 20. The region in which the laminated wiring structure 17 is formed includes the first region 1, the second region 2, and the third region 3 in the direction Y. The region that will later become the bridge part 18 includes the fourth region 4 and the fifth region 5 in the direction Y. The first region 1 and the second region 2 and the fourth region 4 are step regions of the stepped structure, and the sacrificial layer 20 is exposed and formed substantially parallel to the semiconductor substrate Y. The height of the first region 1 from the semiconductor substrate Y is lower than that of the fourth region 4, and the height of the second region 2 from the semiconductor substrate Y is lower than that of the first region 1. For example, the sacrificial layer 27b is exposed in the first region 1, the sacrificial layer 24a below (the semiconductor substrate Y side) the sacrificial layer 27b is exposed in the second region 2, and the sacrificial layer 29b above the sacrificial layer 27b is exposed in the fourth region 4. The step in the step region of the stepped structure is not particularly limited. For example, the sacrificial layer 20 of 6 layers or more and 24 layers or less is preferably disposed between the sacrificial layer 24a and the sacrificial layer 27b.

The third region 3 and the fifth region 5 are the tapered regions connecting the step region of the stepped structure in the direction Y, and the insulating layer 40 is exposed. The third region 3 connects the first region 1 and the second region 2, and the fifth region 5 connects the first region 1 and the fourth region 4. For example, the insulating layer 47b below the sacrificial layer 27b (the semiconductor substrate Y side) is exposed in the third region 3, and the insulating layer 49b below the sacrificial layer 29b (the semiconductor substrate Y side) is exposed in the fifth region 5. The stepped structure of the laminated body of the insulating layer 40 and the sacrificial layer 20 is formed by RIE (Reactive Ion Etching) using a mask having a pattern formed by photolithography. However, the method for forming the stepped structure is not particularly limited.

The thickness of the sacrificial layer 27b exposed in the first region 1, the sacrificial layer 24a exposed in the second region 2, and the sacrificial layer 29b exposed in the fourth region 4 is increased in the direction Z (laminated direction) by depositing silicon nitride (SiN) using the CVD apparatus. As a result, the thickness of the sacrificial layer 27b exposed in the first region 1 is larger than the thickness of the sacrificial layer 27b in the fourth region 4, and the thickness of the sacrificial layer 24a exposed in the second region 2 is larger than the thickness of the sacrificial layer 24a in the first region 1. The insulator 30 embedding the stepped structure is formed on the laminated body of the insulating layer 40 and the sacrificial layer 20.

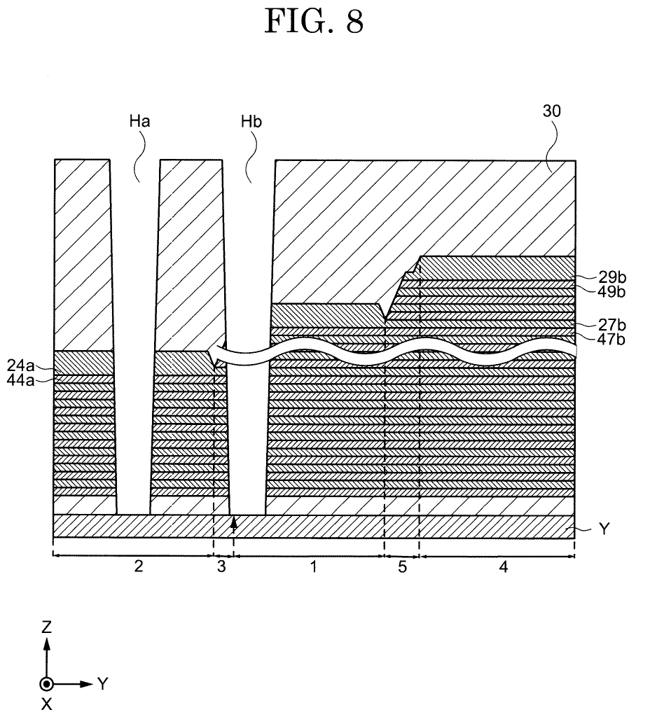

As shown in FIG. 8, a contact hole Ha and a contact hole Hb (when there is no need t distinguish the contact hole Ha and the contact hole Hb, they are collectively referred to as a contact hole H) are formed in the laminated body having the stepped structure. The contact hole H is formed so as to extend in the laminated direction (direction Z) of the laminated body and penetrate the laminated body of the insulator 30 and the insulating layer 40 and the sacrificial layer 20 to reach the semiconductor substrate Y. The contact hole Ha is formed in the second region 2. The contact hole Hb is formed in the first region 1 and the third region 3. The width of the second region 2 in the direction Y is substantially the same as the sum of the width of the first region 1 in the direction Y and the width of the third region 3 in the direction Y. Therefore, the contact hole Hb may be formed at the boundary (dotted arrow) between the first region 1 and the third region 3. The contact hole H is formed by RIE using the mask having the pattern formed by photolithography. The pattern of the mask has an opening exposing the insulator 30 in the region where the contact hole H is formed. However, the method for forming the contact hole H is not particularly limited.

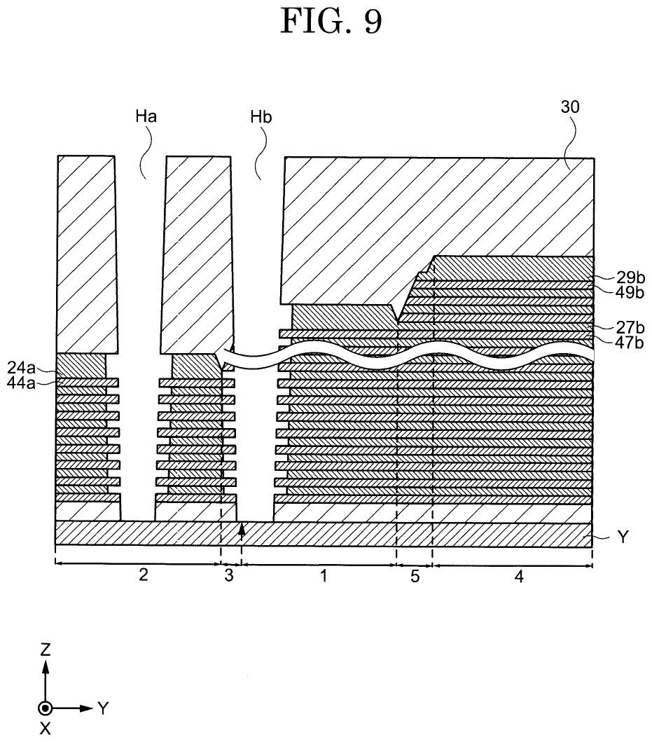

As shown in FIG. 9, the sacrificial layer 20 exposed on the inner surface of the contact hole H is etched. The etching of the sacrificial layer 20 exposed on the inner surface of the contact hole H is preferably performed by selective etching of a silicon nitride film (SiN), and may be, for example, wet etched using phosphoric acid. By etching the sacrificial layer 20, a groove protruding in the outer direction of the contact hole H is formed on the inner surface of the contact hole H. In this case, since the thickness of the sacrificial layer 27b exposed on the inner surface of the contact hole Hb and the thickness of the sacrificial layer 24a exposed on the inner surface of the contact hole Ha is increased in the direction Z (laminated direction), a larger groove is formed in the direction Z (laminated direction) than the sacrificial layer 20 of each lower layer.

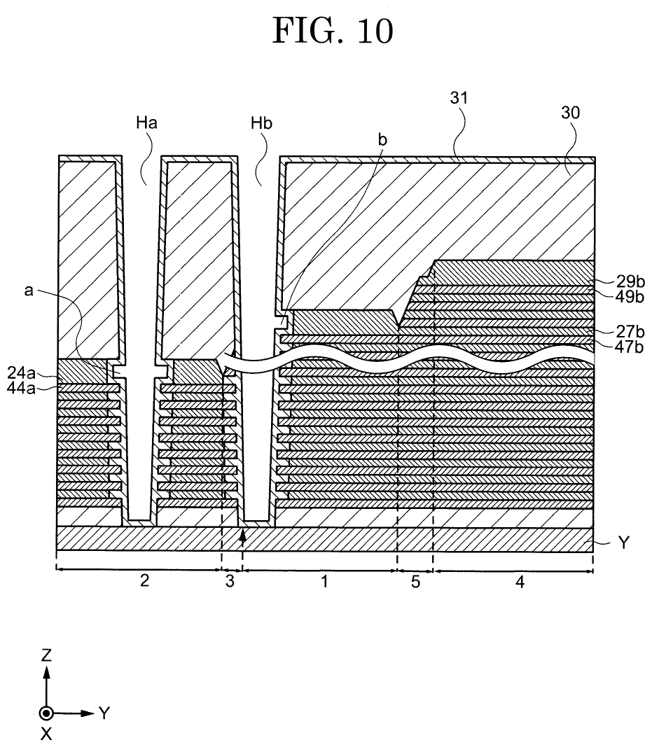

As shown in FIG. 10, the insulating film 31 is formed on the laminated body having the contact hole H. For example, the material of the insulating film 31 may be a silicon dioxide film (SiO₂). For example, the silicon dioxide film (SiO₂) is deposited using the CVD apparatus. By depositing the insulating film 31 on the inner surface of the contact hole H, most of the groove formed by etching the sacrificial layer 20 exposed on the inner surface of the contact hole H is filled with the insulating film 31. On the other hand, since a groove b is formed on the inner surface of the contact hole Hb due to the etching of the sacrificial layer 27b and a groove a is formed on the inner surface of the contact hole Ha due to the etching of the sacrificial layer 24a are large in the direction Z (laminated direction), the groove a and the groove b remain on the inner surfaces of the contact hole Ha and the contact hole Hb, respectively.

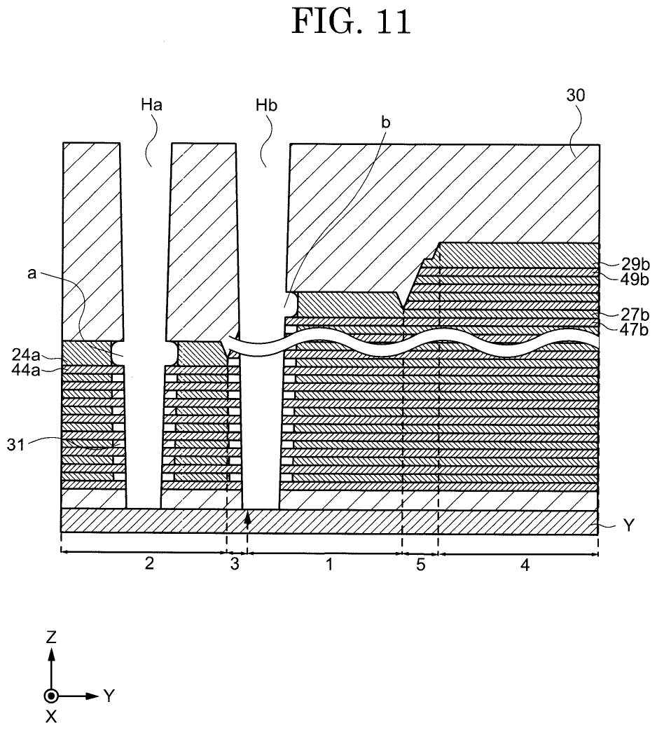

As shown in FIG. 11, the insulating film 31 exposed on the surface of the laminated body having the contact hole H is etched. The etching of the insulating film 31 exposed on the surface of the laminated body is preferably performed by selective etching of a silicon dioxide film (SiO₂), and may be wet etched using, for example, DHF or BHF. By etching the insulating film 31 exposed otnh e surface of the laminated body, the diameter of the contact hole H and the groove b formed on the inner surface of the contact hole Hb due to the etching of the sacrificial layer 27b and the groove a formed on the inner surface of the contact hole Ha due to the etching of the sacrificial layer 24a are increased. On the other hand, since the grooves of the sacrificial layer 20 below the sacrificial layer 27b exposed on the inner surface of the contact hole Hb filled with the insulating film 31, and the grooves of the sacrificial layer 20 below the sacrificial layer 24a exposed on the inner surface of the contact hole Ha are small in the direction Z (laminated direction), the insulating film 31 remains as a spacer between the inner surfaces of the contact hole Hb and the contact hole Ha and the sacrificial layer 20 without being etched.

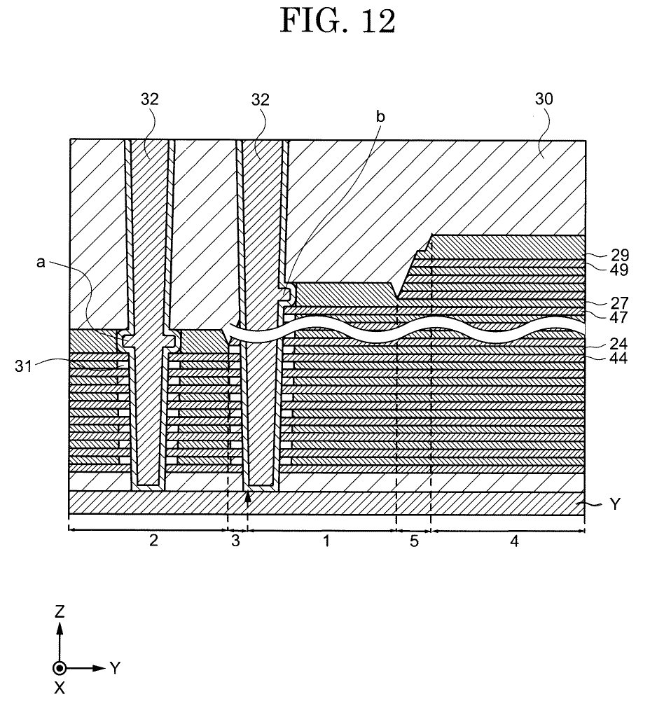

As shown in FIG. 12, an insulator 32 is formed inside the contact hole H. For example, t insulator 32 may have a double-layer structure of a silicon dioxide film (SiO₂) and an amorphous silicon film. For example, the silicon dioxide film (SiO₂) and the amorphous silicon film are deposited using the CVD apparatus.

The conductive layer 70 is formed in a region where the sacrificial layer 20 is disposed. By digging slits (not shown) in a predetermined region of the laminated body, the sacrificial layer 20 included in the laminated body is collectively removed from the slits. As a result, a cavity is formed in the portion where the sacrificial layer 20 was present. Then, by filling the cavity with a metal material such as tungsten or molybdenum, the conductive layer 70 is formed.

Next, the insulator 32 inside the contact hole H is removed by anisotropic etching such as RIE. The etching of the insulator 32 is preferably performed by selective etching of the amorphous silicon film, and may be, for example, RIE using CF4 and oxygen. By removing the insulator 32, the groove b formed on the inner surface of the contact hole Hb due to the etching of the sacrificial layer 27b exposes the conductive layer 77b, and the groove a formed on the inner surface of the contact hole Ha due to the etching of the sacrificial layer 24a exposes the conductive layer 74a.

The contact plug 54a and the contact plug 54b shown in FIG. 6 are formed by embedding a metal material such as tungsten inside the contact hole Ha and the contact hole Hb. The widening portion A of the contact plug 54a and the widening portion B of the contact plug 54b are formed in the groove b formed on the inner surface of the contact hole Hb due to the etching of the sacrificial layer 27b and the groove a formed on the inner surface of the contact hole Ha due to the etching of the sacrificial layer 24a. Therefore, the widening portion A of the contact plug 54a is connected to the conductive layer 74a, and the widening portion B of the contact plug 54b is connected to the conductive layer 77b.

As described above, in the method for manufacturing the laminated wiring structure according to the present embodiment, even if the contact hole Hb is formed in the tapered region of the stepped structure, the spacer remains between the conductive layer 70 below the conductive layer 77b and the inner surface of the contact hole Hb, and the contact plug 54b and the conductive layer 77b can be securely connected, so that the semiconductor device 10 with improved reliability can be provided.

The width in the direction Y of the second region 2 in which the contact plug 54a is formed can be designed to be substantially the same as the sum of the width in the direction Y of the first region 1 in which the contact plug 54b is formed and the width in the direction Y of the third region 3, and the width in the direction Y of the laminated wiring structure 17 can be reduced. Therefore, the width in the direction Y of the bridge part 18 can be increased, and an increase in resistance of the bridge part 18 can be suppressed, so that a semiconductor device in which the operation rate (read and program operation rate) is improved can be provided.

### Second Embodiment

### Overall Configuration of Semiconductor Device

An overall configuration of the semiconductor device according to the second embodiment is the same as the overall configuration of the semiconductor device according to the first embodiment. A configuration of the laminated wiring structure according to the second embodiment is the same as the configuration of the laminated wiring structure according to the first embodiment except for the configuration of the contact plug. Descriptions that are the same as those of the first embodiment will be omitted, and parts different from the configuration of the contact plug according to the first embodiment will be described here.

### Contact Plug Configuration

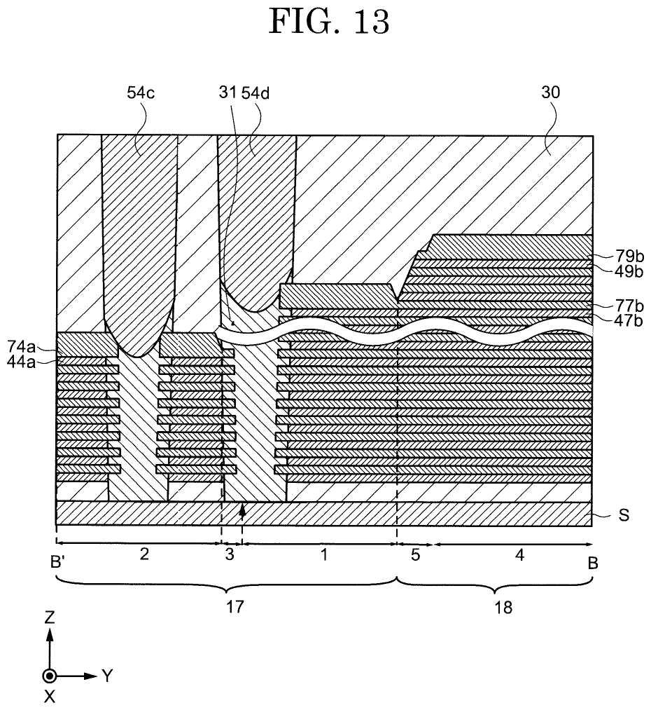

The configuration of the contact plug in the present embodiment will be described with reference to FIG. 13. FIG. 13 corresponds to a cross-sectional view of the contact region HUR shown in FIG. 4 cut along a line B-B′.

As shown in FIG. 13, a contact plug 50c (corresponding to the contact plug 50a in FIG. 4; in this case, when there is no need to distinguish between contact plugs 51c to 55c, they are collectively referred to as the contact plug 50c) and a contact plug 50d (corresponding to the contact plug 50b in FIG. 4; in this case, when there is no need to distinguish between contact plugs 51d to 55d, they are collectively referred to as the contact plug 50d, and when there is no need to distinguish the contact plug 50c and the contact plug 50d, they are collectively referred to as the contact plug 50) extend in the laminated direction (direction Z) of the laminated body and are connected to the conductive layer 70 exposed into the step region of the stepped structure.

The contact plug 50c is disposed in the second region 2. The contact plug 50d is disposed in the first region 1 and the third region 3. The width of the second region 2 in the direction Y is substantially the same as the sum of the width of the first region 1 in the direction Y and the width of the third region 3 in the direction Y. Therefore, the contact plug 50d is disposed at the boundary (dotted arrow) between the first region 1 and the third region 3.

The contact plug 50c is connected to the upper surface of the conductive layer 70 exposed in the step region of the stepped structure in the second region 2. For example, a contact plug 54c is connected to the upper surface of the conductive layer 74a in the second region 2 in the direction Z.

The contact plug 50d is connected to the end portion of the conductive layer 70 exposed in the step region of the stepped structure at the boundary (dotted arrow) between the first region 1 and the third region 3. For example, a contact plug 54d is connected to the end portion of the conductive layer 77b in the direction Y at the boundary between the first region 1 and the third region 3.

The insulating film 31 is disposed between the contact plug 50 and the lower layer conductive layer 70 other than the conductive layer 70 connected to the contact plug 50. The contact plug 50 and the lower layer conductive layer 70 other than the conductive layer 70 connected to the contact plug 50 can be insulated via the insulating film 31.

As described above, in the laminated wiring structure according to the present embodiment, even when the contact plug 54d is disposed in the tapered region of the stepped structure, it is insulated from the conductive layer 70 below the conductive layer 77b, and the contact plug 54d and the conductive layer 77b can be securely connected, so that the semiconductor device 10 with improved reliability can be provided.

The width in the direction Y of the second region 2 in which the contact plug 54c is formed can be designed to be substantially the same as the sum of the width in the direction Y of the first region 1 in which the contact plug 54d is formed and the width in the direction Y of the third region 3, and the width in the direction Y of the laminated wiring structure 17 can be reduced. Therefore, the width of the bridge part 18 in the direction Y can be increased, and an increase in resistance of the bridge part 18 can be suppressed, so that a semiconductor device in which the operation rate (read and program operation rate) is improved can be provided.

### Manufacturing Method for Laminated Wiring Structure

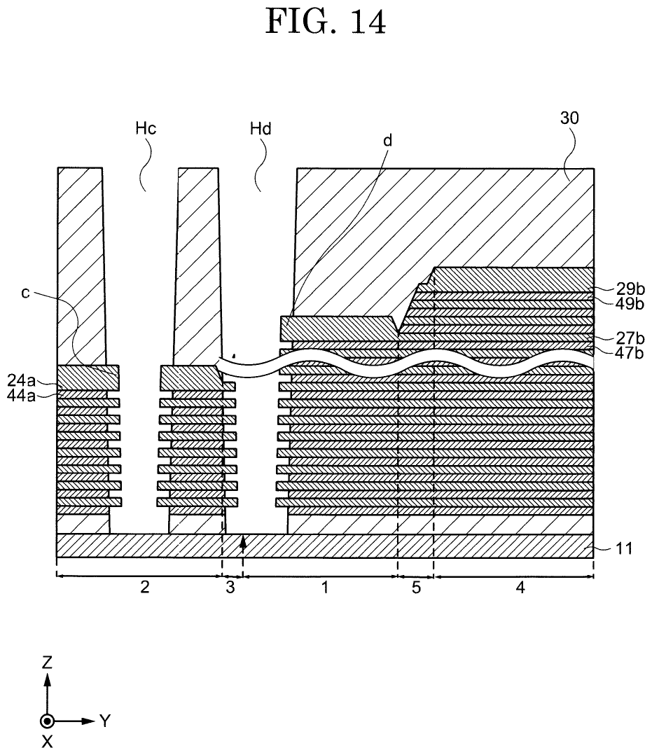

A method for manufacturing the laminated wiring structure 17 according to the present embodiment will be described with reference to FIG. 7, FIG. 8, and FIG. 14 to FIG. 17.

As shown in FIG. 7, the laminated body of the insulating layer 40 and the sacrificial layer 20 is formed in a stepped structure so as to expose the lower layer sacrificial layer 20, similar to FIG. 8, and a contact hole Hc and a contact hole Hd (when there is no need to distinguish the contact hole Hc and the contact hole Hd, they are collectively referred to as the contact hole H) are formed in the laminated body of the stepped structure. The contact hole Hc is formed in the second region 2, and the contact hole Hd is formed in the first region 1 and the third region 3.

As shown in FIG. 14, the insulating layer 40 exposed on the inner surface of the contact hole H is etched. The etching of the insulating layer 40 exposed on the inner surface of the contact hole H is preferably performed by selective etching of the silicon dioxide film, and may be, for example, wet etched using DHF or BHF. By etching the insulating layer 40, the sacrificial layer 20 protrudes inward of the contact hole H on the inner surface of the contact hole H.

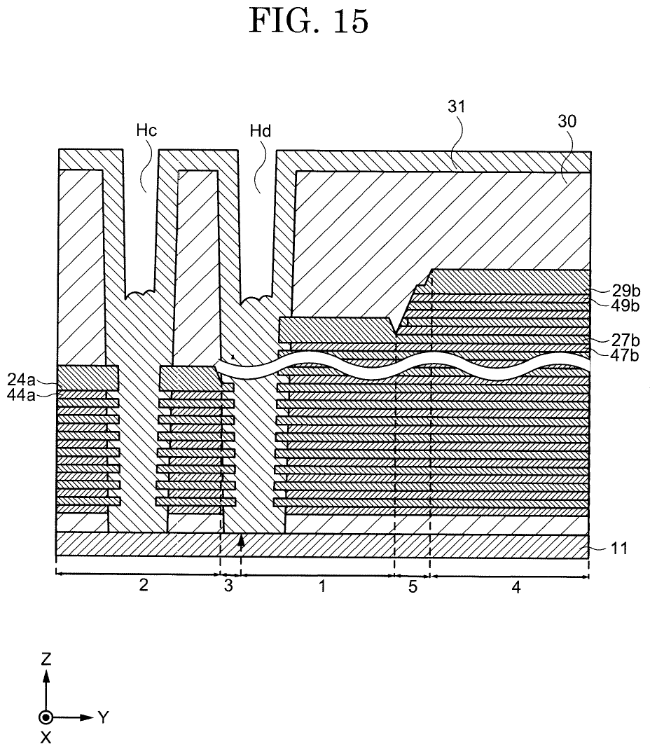

As shown in FIG. 15, the insulating film 31 is formed on the laminated body having the contact hole H. For example, the material of the insulating film 31 may be a silicon dioxide film (SiO₂). For example, the silicon dioxide film (SiO₂) is deposited using the CVD apparatus. By forming the insulating film 31 on the inner surface of the contact hole H, the protrusion part of the sacrificial layer 20 formed by etching the insulating layer 40 exposed on the inner surface of the contact hole H is filled with the insulating film 31.

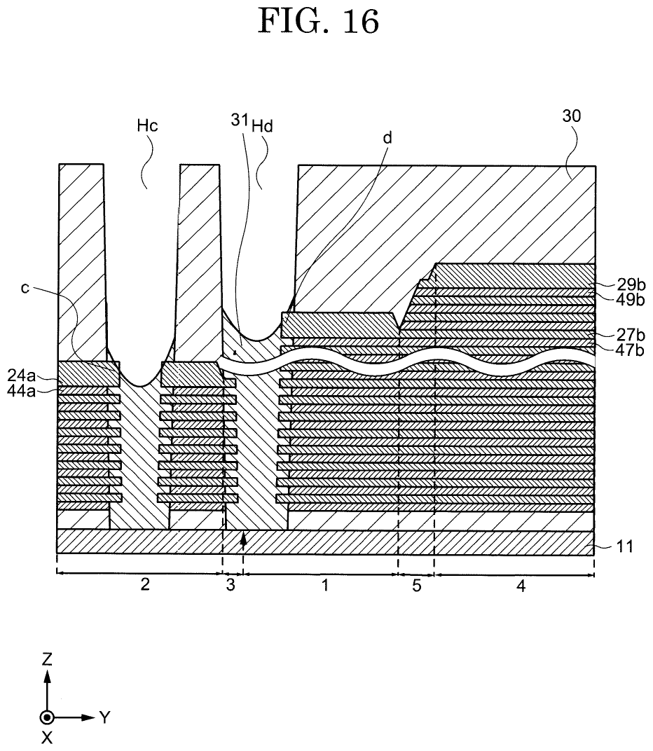

As shown in FIG. 16, the insulating film 31 exposed on the laminated body having the contact hole H is etched. The etching of the insulating film 31 exposed on the laminated body is preferably performed by selective etching of a silicon dioxide film (SiO₂), and may be wet etched using, for example, DHF or BHF. By etching the insulating film 31 exposed on the laminated body, the upper portion of the contact hole H and a protrusion part d of the sacrificial layer 27 formed on the inner surface of the contact hole Hd and a protrusion part c of the sacrificial layer 24 formed on the inner surface of the contact hole Hc are exposed. On the other hand, the insulating film 31 remains as a spacer at the lower portion of the contact hole Hd filled with the insulating film 31 and the lower portion of the contact hole Hc without being etched.

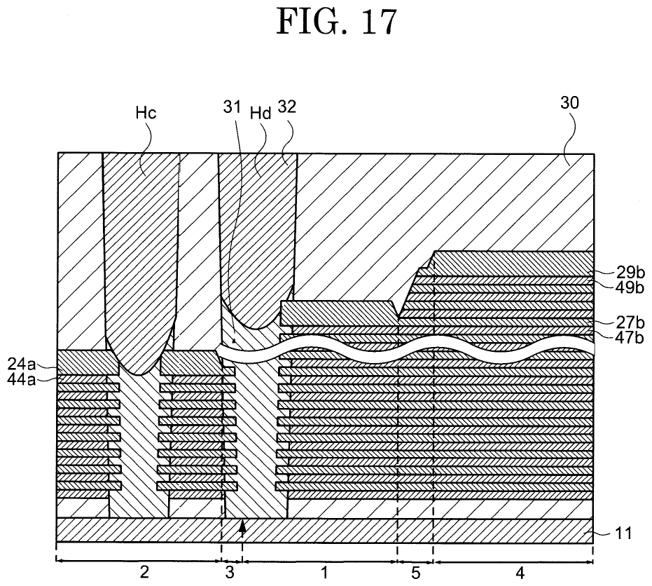

As shown in FIG. 17, the insulator 32 is formed inside the contact hole H. For example, the material of the insulator 32 may have a double-layer structure of a silicon dioxide film (SiO₂) and an amorphous silicon film. For example, the silicon dioxide film (SiO₂) and the amorphous silicon film are deposited using the CVD apparatus.

The conductive layer 70 is formed in a region where the sacrificial layer 20 is disposed. By digging slits (not shown) in a predetermined region of the laminated body, the sacrificial layer 20 included in the laminated body is collectively removed from the slits. As a result, a cavity is formed in the portion where the sacrificial layer 20 was present. Then, by filling the cavity with a metal material such as tungsten or molybdenum, the conductive layer 70 is formed.

Next, the insulator 32 inside the contact hole H is removed by anisotropic etching such as RIE. The etching of the insulator 32 is preferably performed by selective etching of the amorphous silicon film, and may be, for example, RIE using CF4 and oxygen. By removing the insulator 32, the conductive layer 77b protruding on the inner surface of the contact hole Hd is exposed, and the conductive layer 74a protruding on the inner surface of the contact hole Hc is exposed.

The contact plug 54c and the contact plug 54d shown in FIG. 13 are formed by embedding metal material such as tungsten inside the contact hole Hc and the contact hole Hd. Therefore, the contact plug 54c is connected to the conductive layer 74a and the contact plug 54d is connected to the conductive layer 77b.

As described above, in the method for manufacturing the laminated wiring structure according to the present embodiment, even if the contact hole Hd is formed in the tapered region of the stepped structure, the spacer remains between the conductive layer 70 below the conductive layer 77b and the contact plug 54d, and the contact plug 54d and the conductive layer 77b can be securely connected, so that the semiconductor device 10 with improved reliability can be provided.

The width in the direction Y of the second region 2 in which the contact plug 54c is formed can be designed to be substantially the same as the sum of the width in the direction Y of the first region 1 in which the contact plug 54d is formed and the width in the direction Y of the third region 3, and the width in the direction Y of the laminated wiring structure 17 can be reduced. Therefore, the width of the bridge part 18 in the direction Y can be increased, and an increase in resistance of the bridge part 18 can be suppressed, so that a semiconductor device in which the operation rate (read and program operation rate) is improved can be provided.

While certain embodiments have been described, these embodiments have been presented by way of example only, and are not intended to limit the scope of the disclosures. These novel embodiments can be implemented in various other forms, and various omissions, replacements, and modifications can be made without departing from the gist of the disclosure. These embodiments and modifications thereof fall within the scope and spirit of the disclosure, and fall within the scope of the disclosure described in the claims and equivalents thereof.

What is claimed is:

1. A semiconductor device comprising:
a source;
an insulator disposed above the source;
a first conductive layer in contact with the insulator in a first region;
a second conductive layer disposed between the source and the first conductive layer, the second conductive layer being in contact with the insulator in a second region having a lower height from the source than a height from the source of the first region;
a first insulating layer disposed between the first conductive layer and the second conductive layer, the first insulating layer being in contact with the insulator in a third region that connects the first region and the second region in a first direction; and
a first columnar conductor part disposed at a boundary between the first region and the third region, the first columnar conductor part extending in a second direction perpendicular to the first direction, the first columnar conductor part being connected to the first conductive layer.

2. The semiconductor device according to claim 1, further comprising:
a second columnar conductor part disposed in the second region, the second columnar conductor part extending in the second direction and connected to the second conductive layer.

3. The semiconductor device according to claim 2, wherein a width of the second region in the first direction is a sum of the width of the first region in the first direction and a width of the third region in the first direction.

4. The semiconductor device according to claim 1, further comprising:
a third conductive layer disposed on the opposite side of the first conductive layer from the source side, the third conductive layer being in contact with the insulator in a fourth region having a higher height from the source than the height from the source of the first region; and
a second insulating layer disposed between the first conductive layer and the third conductive layer, the second insulating layer being in contact with the insulator in a fifth region connecting the first region and the fourth region in the first direction.

5. The semiconductor device according to claim 1, wherein the first columnar conductor part has a first widening portion in a first portion facing the first conductive layer, the first widening portion having a width in the first direction larger than a width in a second portion facing the first insulating layer.

6. The semiconductor device according to claim 5, wherein the first widening portion of the first columnar conductor part is connected to the first conductive layer.

7. The semiconductor device according to claim 4, wherein the first conductive layer has a thickness larger in the first region than in the fourth region.

8. The semiconductor device according to claim 2, further comprising:
a third insulating layer disposed between the source and the second conductive layer,
wherein the second columnar conductor part has a second widening portion in a third portion facing the second conductive layer, the second widening part having a width in the first direction larger than a width in a fourth portion facing the third insulating layer.

9. The semiconductor device according to claim 8, wherein the second widening portion of the second columnar conductor part is connected to the second conductive layer.

10. The semiconductor device according to claim 1, wherein the second conductive layer has a thickness larger in the second region than that of the first region.

11. A manufacturing method for manufacturing a semiconductor memory device, the manufacturing method comprising:
forming a stacked body by alternately stacking first insulating layers and second insulating layers in a first direction to form a stacked body, the stacked body includes a first region, a second region and a third region which is between the first region and the second region;
forming a stepped structure so as to expose at least one of the second insulating layer that is lower than another at least one of the second insulating layers;
forming a hole at a boundary between the first region and the third region;
etching the second insulating layers exposed on an inner surface of the hole H;
forming a spacer on the inner surface of the hole H;
removing the second insulating layers;
forming conductive layers in a region where the second insulating layers are removed; and
forming a contact in the hole, the contact is connected to at least one of the conductive layers.
